(19) United States
(12) Patent Application Publication
(10) Pub. No.: US 2015/0274437 A1
(43) Pub. Date: Oct. 1, 2015

(54) APPARATUS FOR AND METHOD OF HANDLING WORKPIECES

(71) Applicant: DTG INTERNATIONAL GMBH, Zurich (CH)

(72) Inventor: Chris Hawkins, Dorset (GB)

(21) Appl. No.: 14/436,528

(22) PCT Filed: Oct. 17, 2013
(86) PCT No.: PCT/EP2013/071691

§ 371 Date: Apr. 17, 2015

(30) Foreign Application Priority Data
Oct. 17, 2012 (GB) 1218594.8

(51) Int. Cl. B65G 47/248; H01L 21/68

(52) U.S. Cl. CPC B65G 47/248; H01L 21/68

(57) ABSTRACT

A workpiece inverting apparatus for and method of handling workpieces, the apparatus comprising: an infeed station at which workpieces are received; an outfeed station from which workpieces are delivered; and a workpiece inverting device which is operable to deliver a workpiece from the infeed station to the outfeed station in one of an orient as received at the infeed station or Can inverted orient from the orient as received at the infeed station.

The present invention relates to an apparatus for and a method of handling workpieces, in particular planar substrates, such as wafers, for example, fuel or solar cell wafers.

Various apparatus exist for inverting workpieces, being commonly referred to as flippers.

It is an aim of the present invention to provide an improved workpiece handling apparatus, which inter alia allows for a greater workpiece throughput.

In one aspect the present invention provides a workpiece handling apparatus for handling workpieces, comprising: an infeed station at which workpieces are received; an outfeed station from which workpieces are delivered; and a workpiece inverting device which is operable to deliver a workpiece from the infeed station to the outfeed station in one of an orient as received at the infeed station or an inverted orient from the orient as received at the infeed station.

In one embodiment the infeed station comprises a workpiece transport device by which workpieces are transported to the infeed station, and by which workpieces can be transported from the infeed station to the outfeed station in the one orient.

In one embodiment the outfeed station comprises a workpiece transport device by which workpieces are transported from the outfeed station, and by which workpieces can be transported from the infeed station to the outfeed station in the one orient.

In one embodiment the workpiece inverting device comprises first and second workpiece support members which are movably disposed relative to the infeed and outfeed stations, by which workpieces are delivered from the infeed station to the outfeed station in the inverted orient, and a drive assembly for moving the workpiece support members.

In one embodiment the workpiece support members are rotatable around a location which is between the infeed and outfeed stations.

In one embodiment the workpiece support members are each rotatable between a first, workpiece-receiving position in which the workpiece support member is adjacent a lower surface of a workpiece when located at the infeed station and disposed so as to allow a workpiece to pass thereover when being transported to the infeed station, and a second, workpiece-releasing position in which the workpiece support member is adjacent an upper surface of a workpiece when located at the outfeed station and being disposed so as to allow a workpiece to pass thereunder when being transported to or from the outfeed station.

In one embodiment the workpiece support members each comprise a support which supports a workpiece when being transferred from the infeed station to the outfeed station, and an arm by which the support is rotated between the infeed and outfeed stations.

In one embodiment the support has a planar support surface and includes at least one suction aperture, optionally a plurality of suction apertures, by which a reduced pressure or vacuum is applied to a workpiece in order to hold the same in a fixed position to the support.

In one embodiment the drive assembly comprises a first drive member to which the first workpiece support member is attached and a second drive member to which the second workpiece support member is attached.

In one embodiment the drive members are rotatable about an axis substantially perpendicular to a transport direction between the infeed and outfeed stations.

In one embodiment the drive members are independently rotatable relative to one another, allowing for the drive members to be rotated at different relative speeds, at least through part of a rotational phase.

In one embodiment the drive members extend laterally at a location between the infeed and outfeed stations.

In one embodiment the drive members are supported at ends thereof by first and second bearings.

In one embodiment the first drive member comprises an elongate, first drive element, one end of which is supported by the first bearing and the other end of which is supported by the second bearing.

In one embodiment the second drive member comprises an elongate, second drive element, one end of which is supported by the second bearing and the other end of which is supported by the first bearing.

In one embodiment the one end of the first drive element comprises a bore and the other end of the second drive element comprises a projection which is rotatably supported, optionally journalled, in the bore at the one end of the first drive element, and the one end of the second drive element comprises a bore and the other end of the first drive element comprises a projection which is rotatably supported, optionally journalled, in the bore at the one end of the second drive element.

In one embodiment the drive members are supported at one end thereof by respective ones of first and second bearings.

In one embodiment the first drive member comprises an elongate, first drive element, one end of which is supported by the first bearing.

In one embodiment the second drive member comprises an elongate, second drive element, one end of which is supported by the second bearing.

In one embodiment the first drive member is attached to the first workpiece support member, such that the first workpiece support member is rotated with rotation of the first drive member.

In one embodiment the second drive member is attached to the second workpiece support member, such that the second workpiece support member is rotated with rotation of the second drive member.

In one embodiment the drive members are arranged in offset relation, such that, when the workpiece support members are in respective ones of the workpiece-receiving and workpiece-release positions, the workpiece support members provide a horizontally-extending aperture therebetween, which allows a workpiece to be transferred therebetween from the infeed to the outfeed stations in the same orient.

In another aspect the present invention provides a workpiece inverting device for delivering workpieces selectively from an infeed station to an outfeed station in one of an orient as received at the infeed station or an inverted orient from the orient as received at the infeed station, wherein the workpiece inverting device comprises: first and second workpiece support members which are movably disposed relative to the infeed and outfeed stations, by which workpieces are delivered from the infeed station to the outfeed station in the inverted orient; and a drive assembly which comprises a first drive member to which the first workpiece support member is attached and a second drive member to which the second workpiece support member is attached; wherein the drive members are arranged in offset relation such as to provide a horizontally-extending aperture therebetween, which allows a workpiece to be transferred therebetween from the infeed to the outfeed stations in the same orient.

In a further aspect the present invention provides a method of handling workpieces, comprising the steps of: providing an infeed station at which workpieces are received; providing an outfeed station from which workpieces are delivered; providing a workpiece inverting device which is operable to deliver a workpiece from the infeed station to the outfeed station in one of an orient as received at the infeed station or an inverted orient from the orient as received at the infeed station; and selectively operating the workpiece inverting device to deliver workpieces from the infeed station to the outfeed station in one of a pass-through mode, in which workpieces delivered to the outfeed station have an orient as received at the infeed station or an inverting mode, in which workpieces delivered to the outfeed station have an inverted orient from the orient of the workpieces as received at the infeed station.

In one embodiment the infeed station comprises a workpiece transport device by which workpieces are transported to the infeed station, and by which workpieces can be transported from the infeed station to the outfeed station in the one orient.

In one embodiment the outfeed station comprises a workpiece transport device by which workpieces are transported from the outfeed station, and by which workpieces can be transported from the infeed station to the outfeed station in the one orient.

In one embodiment the workpiece inverting device comprises first and second workpiece support members which are movably disposed relative to the infeed and outfeed stations, by which workpieces are delivered from the infeed station to the outfeed station in the inverted orient, and a drive assembly for moving the workpiece support members.

In one embodiment the workpiece support members are rotatable around a location which is between the infeed and outfeed stations.

In one embodiment the workpiece support members are each rotatable between a first, workpiece-receiving position in which the workpiece support member is adjacent a lower surface of a workpiece when located at the infeed station and disposed so as to allow a workpiece to pass thereover when being transported to the infeed station, and a second, workpiece-releasing position in which the workpiece support member is adjacent an upper surface of a workpiece when located at the outfeed station and being disposed so as to allow a workpiece to pass thereunder when being transported to or from the outfeed station.

In one embodiment the workpiece support members each comprise a support which supports a workpiece when being transferred from the infeed station to the outfeed station, and an arm by which the support is rotated between the infeed and outfeed stations.

In one embodiment the support has a planar support surface and includes at least one suction aperture, optionally a plurality of suction apertures, by which a reduced pressure or vacuum is applied to a workpiece in order to hold the same in a fixed position to the support.

In one embodiment the drive assembly comprises a first drive member to which the first workpiece support member is attached and a second drive member to which the second workpiece support member is attached.

In one embodiment the drive members are rotatable about an axis substantially perpendicular to a transport direction between the infeed and outfeed stations.

In one embodiment the drive members are independently rotatable relative to one another, allowing for the drive members to be rotated at different relative speeds, at least through part of a rotational phase.

In one embodiment the drive members extend laterally at a location between the infeed and outfeed stations.

In one embodiment the drive members are supported at ends thereof by first and second bearings.

In one embodiment the first drive member comprises an elongate, first drive element, one end of which is supported by the first bearing and the other end of which is supported by the second bearing.

In one embodiment the second drive member comprises an elongate, second drive element, one end of which is supported by the second bearing and the other end of which is supported by the first bearing.

In one embodiment the one end of the first drive element comprises a bore and the other end of the second drive element comprises a projection which is rotatably supported, optionally journalled, in the bore at the one end of the first drive element, and the one end of the second drive element comprises a bore and the other end of the first drive element comprises a projection which is rotatably supported, optionally journalled, in the bore at the one end of the second drive element.

In one embodiment the drive members are supported at one end thereof by respective ones of first and second bearings.

In one embodiment the first drive member comprises an elongate, first drive element, one end of which is supported by the first bearing.

In one embodiment the second drive member comprises an elongate, second drive element, one end of which is supported by the second bearing.

In one embodiment the first drive member is attached to the first workpiece support member, such that the first workpiece support member is rotated with rotation of the first drive member.

In one embodiment the second drive member is attached to the second workpiece support member, such that the second workpiece support member is rotated with rotation of the second drive member.

In one embodiment the drive members are arranged in offset relation, such that, when the workpiece support members are in respective ones of the workpiece-receiving and workpiece-release positions, the workpiece support members provide a horizontally-extending aperture therebetween, which allows a workpiece to be transferred therebetween from the infeed to the outfeed stations in the same orient.

In one embodiment, in the pass through mode, the operating step comprises the steps of: arranging workpiece support members in a configuration which allows a workpiece to be transported therebetween; transporting a workpiece from the infeed station to the outfeed station in the one orient by operation of infeed and outfeed transport devices.

In one embodiment, in an inverting mode, the operating step comprises the steps of: engaging a workpiece to a first workpiece support member which is disposed therebeneath in a workpiece-receiving position at the infeed station, optionally by vacuum or reduced pressure; rotating the first workpiece support member to a workpiece-releasing position at the outfeed station; transporting a workpiece, if present, from the outfeed station during rotation of the first workpiece support member; rotating a second workpiece support member from a workpiece releasing position at the outfeed station to a workpiece-receiving position at the infeed station; transporting a workpiece to the infeed station during rotation of the second workpiece support member to the infeed station; and disengaging the workpiece which is engaged to the first workpiece support member when disposed at the outfeed station.

A preferred embodiment of the present invention will now be described hereinbelow by way of example only with reference to the accompanying drawings, in which:

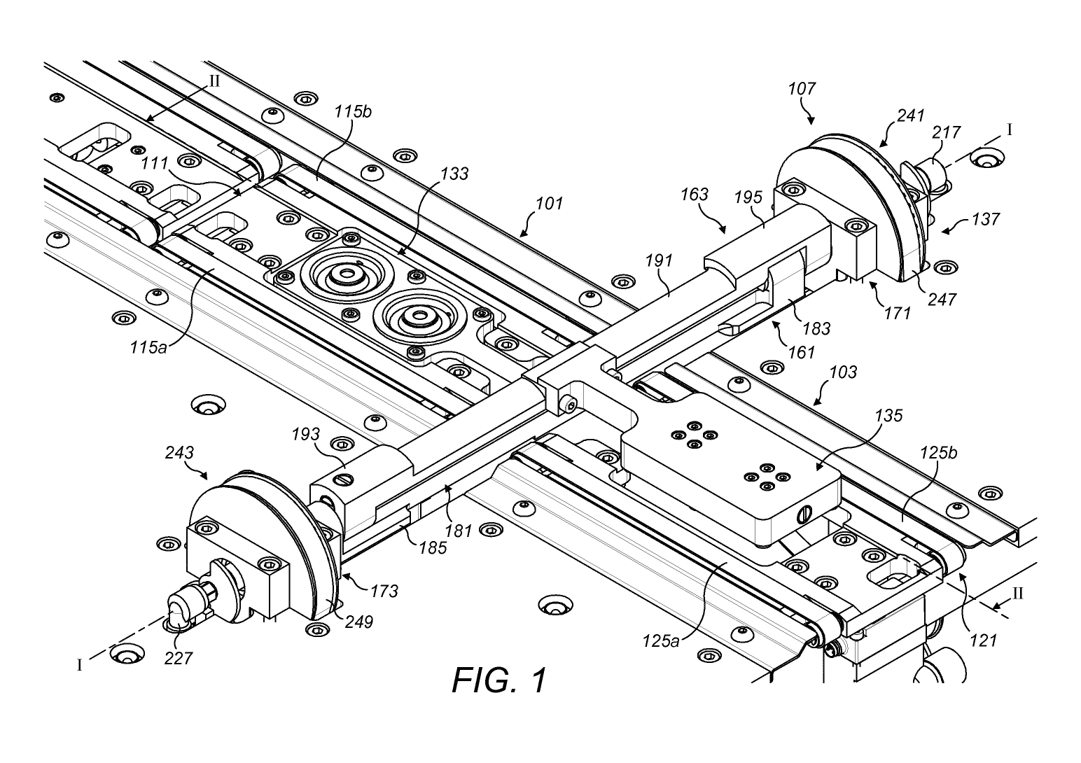

FIG. 1 illustrates a perspective view of a workpiece inverting apparatus in accordance with a preferred embodiment of the present invention;

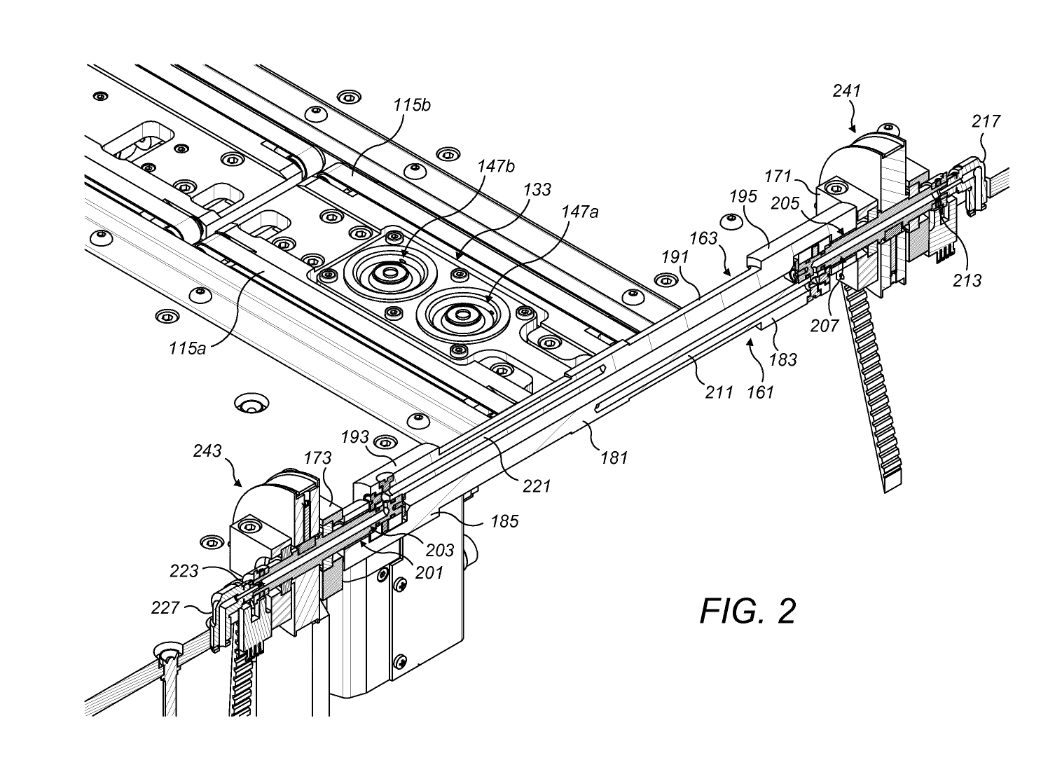

FIG. 2 illustrates a vertical section view (along section I-I of FIG. 1) of the workpiece inverting apparatus of FIG. 1;

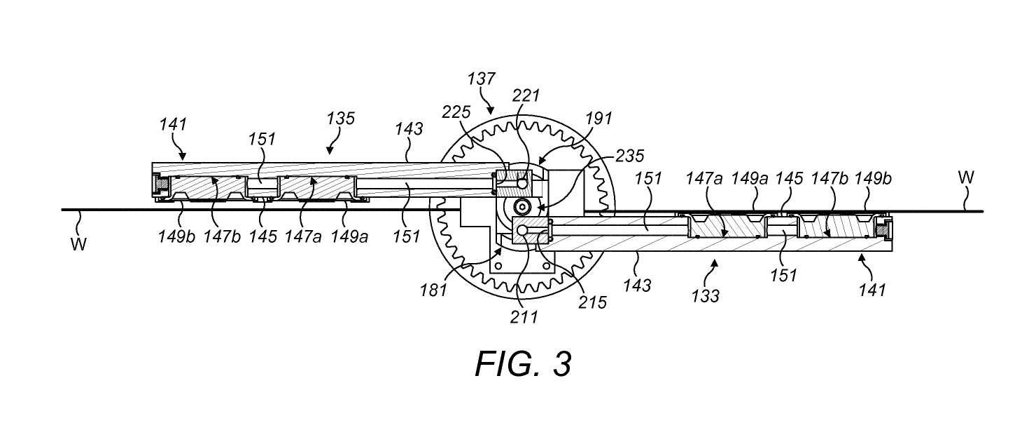

FIG. 3 illustrates a vertical sectional view (along section II-II of FIG. 1) of the workpiece inverting apparatus of FIG. 1; and

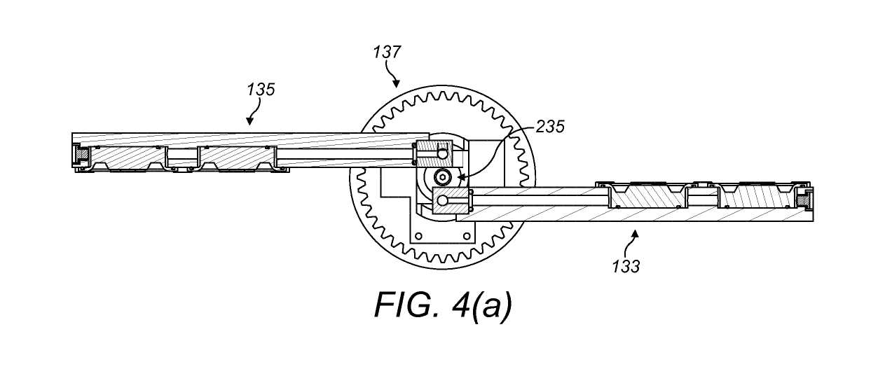

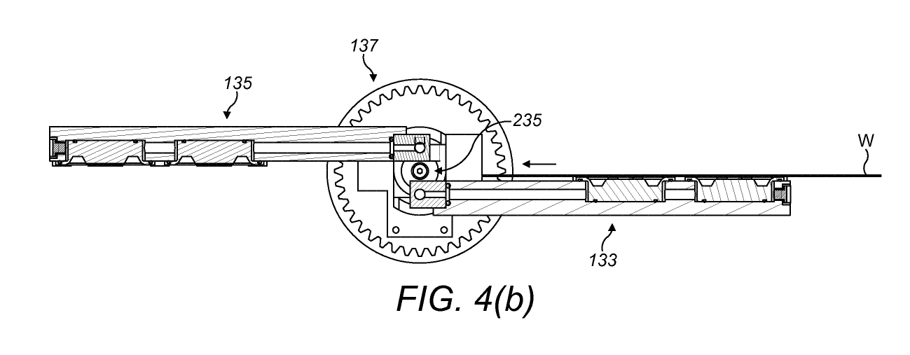

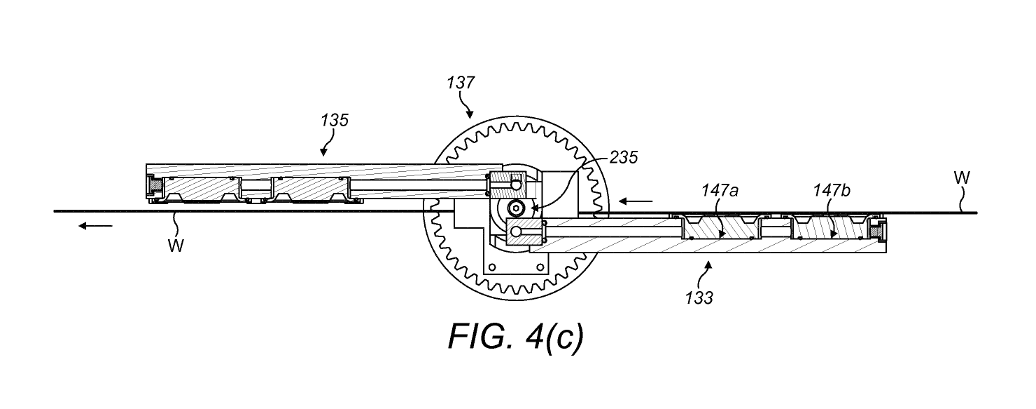

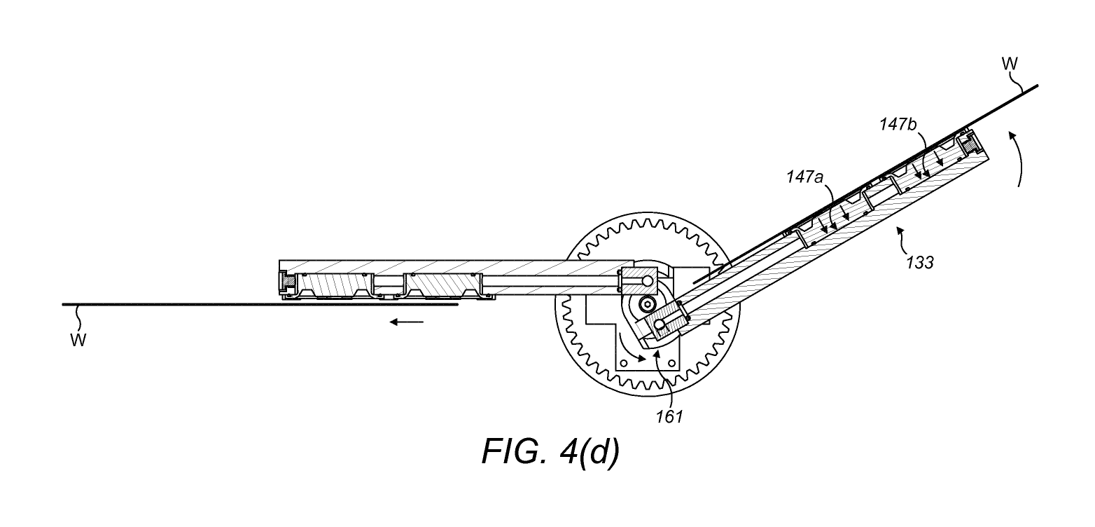

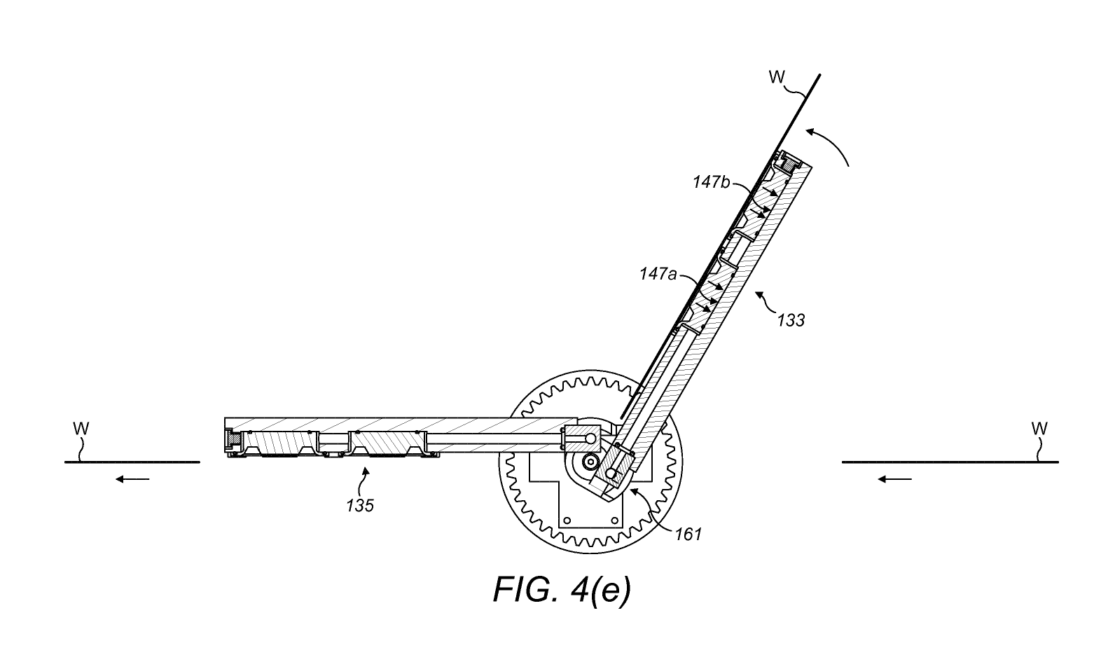

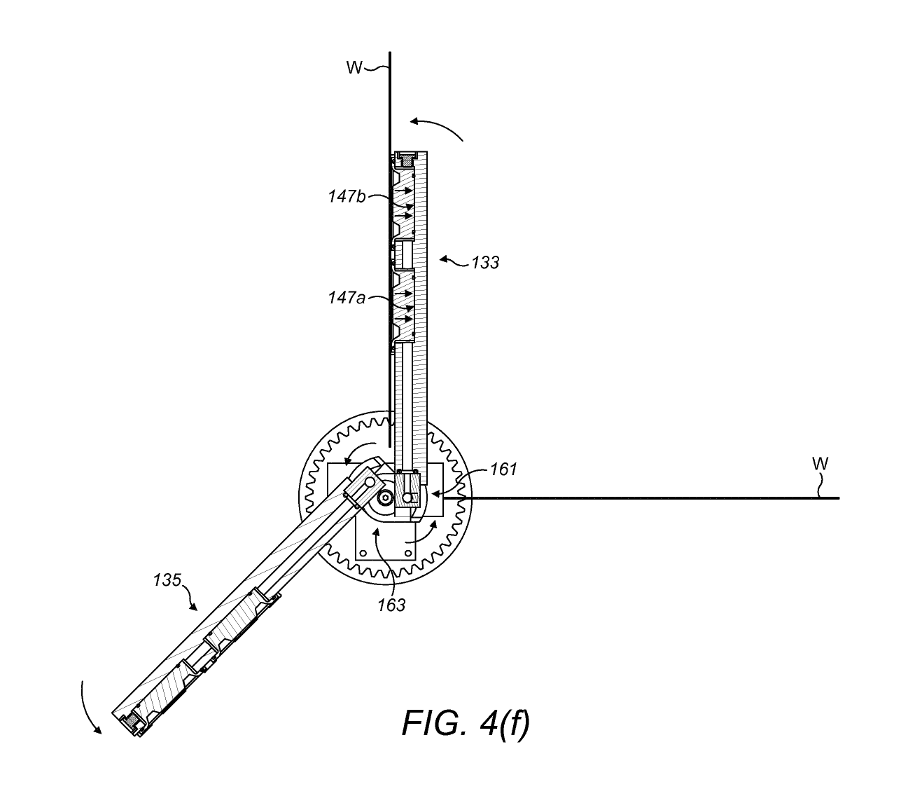

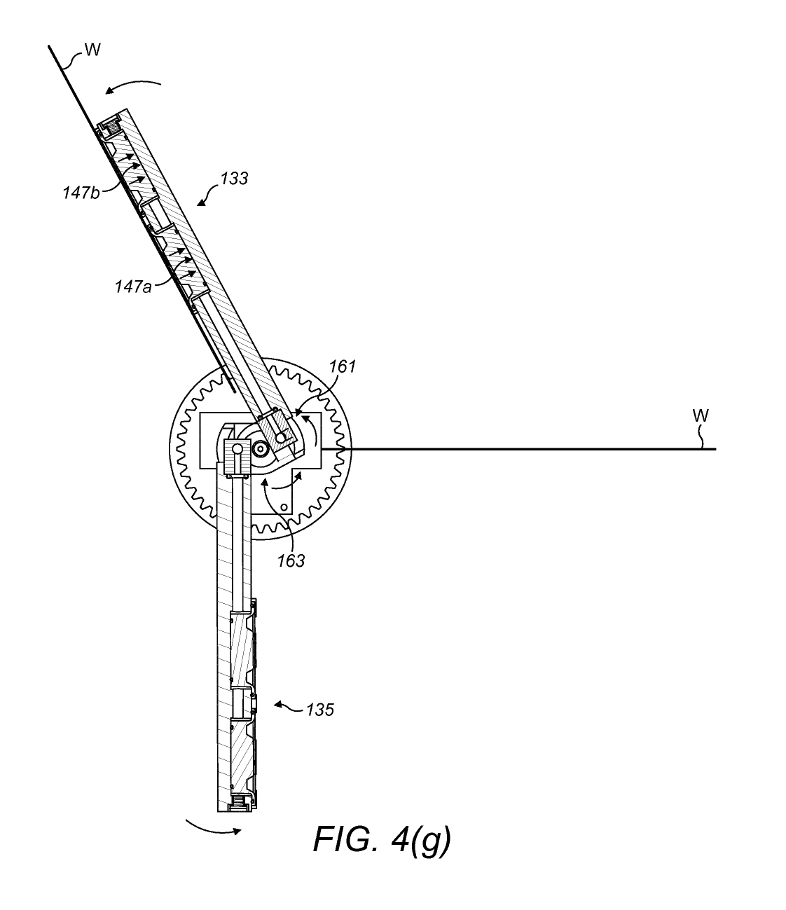

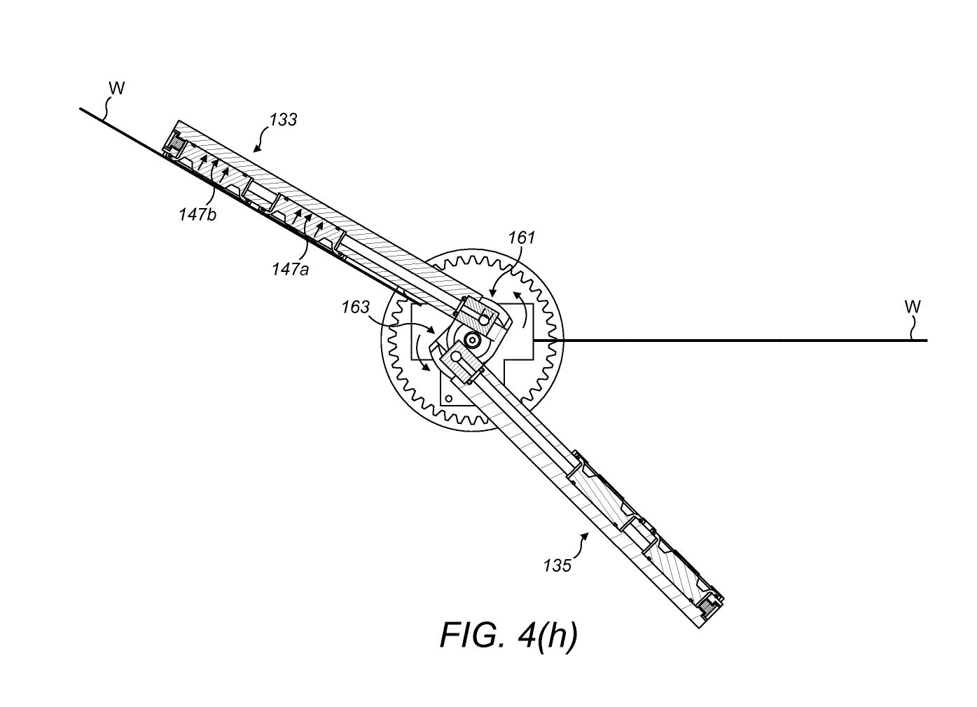

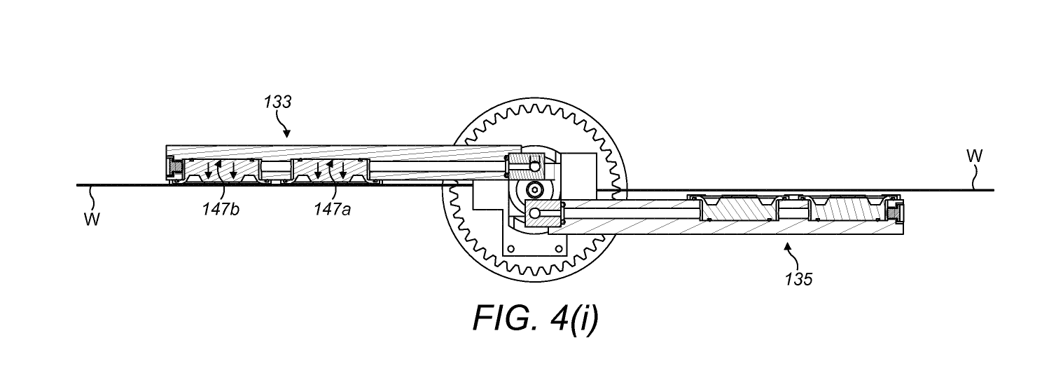

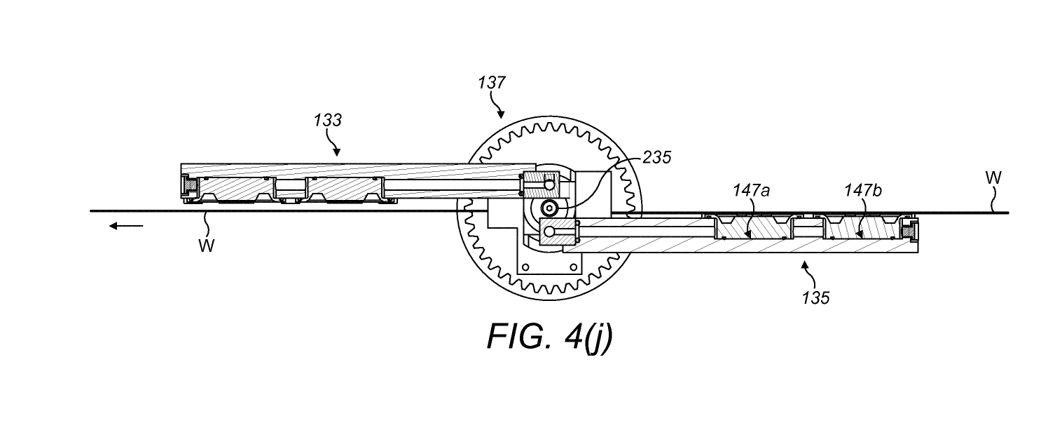

FIGS. 4(a) to (j) illustrate vertical sectional views (along section II-II in FIG. 1) of the operative sequence of the workpiece inverting apparatus of FIG. 1.

The workpiece inverting apparatus comprises an infeed station 101 to which workpieces W are successively transported, an outfeed station 103 from which workpieces W are successively transported, and a workpiece inverting device 107 which is operable to deliver a workpiece W from the infeed station 101 to the outfeed station 103 in an inverted orient, as required.

The infeed station 101 comprises a workpiece transport device 111 by which workpieces W are transported to the infeed station 101, and by which workpieces W can be transported from the infeed station 101 to the outfeed station 103 in the same orient.

In this embodiment the infeed workpiece transport device 111 comprises at least one transport belt 115, here a pair of belts 115a, b which are arranged in spaced relation along a length of the infeed station 101 and operative to engage a lower surface of the workpiece W.

In one alternative embodiment the infeed workpiece transport device 111 could comprise a walking beam.

In another alternative embodiment the infeed workpiece transport device 111 could comprise a fluidized bed, such as a gas cushion.

The outfeed station 103 comprises a workpiece transport device 121 by which workpieces W are transported from the outfeed station 103, and by which workpieces W can be transported from the infeed station 101 to the outfeed station 103 in the same orient.

In this embodiment the outfeed workpiece transport device 121 comprises at least one transport belt 125, here a pair of belts 125a, b which are arranged in spaced relation along a length of the outfeed station 103 and engage a lower surface of the workpiece W to transport the workpiece W when supported thereby.

In one alternative embodiment the outfeed workpiece transport device 121 could comprise a walking beam.

In another alternative embodiment the outfeed workpiece transport device 121 could comprise a fluidized bed, such as a gas cushion.

In this embodiment the workpiece inverting device 107 comprises first and second workpiece support members 133, 135 which are movably disposed relative to the infeed and outfeed stations 101, 103, by which workpieces W are delivered from the infeed station 101 to the outfeed station 103 in an inverted orient, and a drive assembly 137 for moving the workpiece support members 133, 135.

In this embodiment the workpiece support members 133, 135 are rotatable around a location which is between the infeed and outfeed stations 101, 103.

In this embodiment the workpiece support members 133, 135 are each rotatable between a first, workpiece-receiving position in which the workpiece support member 133, 135 is adjacent a lower surface of a workpiece W when located at the infeed station 101, as illustrated in FIG. 4(b), with the workpiece support member 133, 135 being located such as to allow a workpiece W to pass thereover in being transported to the infeed station 101, and a second, workpiece-releasing position in which the workpiece support member 133, 135 is adjacent an upper surface of a workpiece W when located at the outfeed station 103, as illustrated in FIG. 4(j), with the workpiece support member 133, 135 being located such as to allow a workpiece W to pass thereunder in being transported to or from the outfeed station 103.

In this embodiment the workpiece support members 133, 135 each comprise a support 141 which supports a workpiece W when being transferred from the infeed station 101 to the outfeed station 103, and an arm 143 by which the support 141 is rotated between the infeed and outfeed stations 101, 103.

In this embodiment the support 141 has a planar support surface 145, and includes at least one suction aperture 147, here a plurality of suction apertures 147a, b, by which a reduced pressure or vacuum is applied to a workpiece W in order to hold the same in a fixed position to the support 141.

In this embodiment the support 141 includes at least one suction element 149, here a plurality of suction elements 149a, b in the support surface 143, which are each located in a respective suction aperture 147a, b.

In this embodiment the suction elements 149a, b are provided by a suction gasket, such as of rubber.

In this embodiment the support 141 and the arm 143 include a fluid conduit 151 which is fluidly connected to the suction apertures 147a, b and by which a vacuum or reduced pressure is applied thereto, as will be described in more detail hereinbelow.

In this embodiment the drive assembly 137 comprises a first drive member 161 to which the first workpiece support member 133 is attached and a second drive member 163 to which the second workpiece support member 135 is attached, with both of the drive members 161, 163 being rotatable about an axis substantially perpendicular to the infeed and outfeed stations 101, 103.

In this embodiment the drive members 161, 163 are independently rotatable relative to one another, allowing for the drive members 161, 163 to be rotated at different relative speeds, at least through part of the rotational phase.

In this embodiment the drive members 161, 163 extend laterally at a location between the infeed and outfeed stations 101, 103.

In this embodiment the drive members 161, 163 are supported by first and second bearings 171, 173 which are disposed to respective sides of the infeed and outfeed stations 101, 103 in a direction of transport.

In this embodiment the first drive member 161 comprises an elongate, first drive element 181, one end 183 of which is supported by the first bearing 171 and the other end 185 of which is supported by the second bearing 173.

In an alternative embodiment the first drive element 181 could be supported at only the one end 183 by the first bearing 171, and extend to position intermediate the respective sides of the infeed and outfeed stations 101, 103 in a direction of transport.

In this embodiment the second drive member 163 comprises an elongate, second drive element 191, one end 193 of which is supported by the second bearing 173 and the other end 195 of which is supported by the first bearing 171.

In an alternative embodiment the second drive element 191 could be supported at only the one end 193 by the second bearing 173, and extend to a position intermediate the respective sides of the infeed and outfeed stations 101, 103 in a direction of transport.

In this embodiment the other end 185 of the first drive element 181 comprises a bore 201, which provides a sleeve, here cylindrical in shape, and the one end 193 of the second drive element 191 comprises a projection 203, here circular in shape, which is rotatably supported, here journalled, in the bore 201 at the other end 185 of the first drive element 181.

In this embodiment the other end 195 of the second drive element 191 comprises a bore 205, which provides a sleeve, here cylindrical in shape, and the one end 183 of the first drive element 181 comprises a projection 207, here circular in shape, which is rotatably supported, here journalled, in the bore 205 at the other end 195 of the second drive element 191.

In this embodiment the first drive element 181 is attached to the first workpiece support member 133, such that the first workpiece support member 133 is rotated, here in unison, with the first drive element 181.

In this embodiment the first workpiece support member 133 is attached substantially to the mid point of the first drive element 181.

In an alternative embodiment, where the first drive element 181 is supported only at the one end 183, the first workpiece support member 133 could be attached substantially to the distal end of the first drive element 181.

In this embodiment the first workpiece support member 133 is removably attached to the first drive element 181, here by threaded couplings.

In this embodiment the first drive element 181 includes a fluid conduit 211 which extends along a length thereof from a first fluid port 213 at the one end 183 of the first drive element 181 to a second fluid port 215 which in this embodiment is between the ends 183, 185 of the first drive element 181 and corresponds to the location at which the first workpiece support member 133 is attached.

In this embodiment the first fluid port 213 at the one end 183 of the first drive element 181 is located at the longitudinal, distal end of the one end 183, thereby enabling rotation of the first drive element 181 and fluid connection to a first vacuum or reduced pressure source 217.

With this arrangement, a fluid connection path is provided between the one end 183 of the first drive element 181 and the suction apertures 147a, b at the first support member 133, thereby enabling the selective application of vacuum to the suction apertures 147a, b at the first support member 133.

In this embodiment the second drive element 191 is attached to the second workpiece support member 135, such that the second workpiece support member 135 is rotated, here in unison, with the second drive element 191.

In this embodiment the second workpiece support member 135 is attached substantially to a mid point of the second drive element 191.

In an alternative embodiment, where the second drive element 191 is supported only at the one end 193, the second workpiece support member 135 could be attached substantially to the distal end of the second drive element 191.

In this embodiment the second workpiece support member 135 is removably attached to the second drive element 191, here by threaded couplings.

In this embodiment the second drive element 191 includes a fluid conduit 221 which extends along a length thereof from a first fluid port 223 at the one end 193 of the second drive element 191 to a second fluid port 225 which in this embodiment is between the ends 193, 195 of the second drive element 191 and corresponds to the location at which the second workpiece support member 135 is attached.

In this embodiment the first fluid port 223 at the one end 193 of the second drive element 191 is located at the longitudinal, distal end of the one end 193, thereby enabling rotation of the second drive element 191 and fluid connection to a second vacuum or reduced pressure source 227.

With this arrangement, a fluid connection path is provided between the one end 193 of the second drive element 191 and the suction apertures 147a, b at the second support member 135, thereby enabling the selective application of vacuum to the suction apertures 147a, b at the second support member 135.

In this embodiment the drive members 161, 163 are arranged in offset relation, such that, when the workpiece support members 133, 135 are in respective ones of the engagement and release positions, the workpiece support members 133, 135 provide a horizontally-extending aperture 235 therebetween, which allows a workpiece W to be transferred therebetween from the infeed to the outfeed stations 101, 103 in the same orient, as illustrated in FIGS. 4(f) and (g).

In this embodiment the drive assembly 137 comprises a first drive unit 241 for driving the first drive member 161 and a second drive unit 243 for driving the second drive member 163.

In this embodiment the first drive unit 241 comprises a belt 247, here a toothed belt, which is coupled to the first drive member 161, here the one end 183 of the first drive member 161, and is driven by an actuator, such as a motor, to rotate the first drive member 161.

In this embodiment the second drive unit 243 comprises a belt 249, here a toothed belt, which is coupled to the second drive member 163, here the one end 193 of the second drive member 163, and is driven by an actuator, such as a motor, to rotate the second drive member 163.

Operation of the above-described workpiece inverting apparatus will now be described in more detail hereinbelow.

FIG. 4(a) illustrates the workpiece inverting apparatus in a workpiece-receiving configuration.

As illustrated in FIG. 4(b), a workpiece W is first transported to the infeed station 101 by operation of the infeed transport device 111.

Then, under the control of a controller (not illustrated), a determination is made as to whether to deliver the first-received workpiece W in the same orient or an inverted orient to the outfeed station 103.

Where the first-received workpiece W is to be delivered in the same orient to the outfeed station 103, the drive assembly 137 is not operated, such that the workpiece support members 133, 135 remain in the workpiece-receiving configuration, and the infeed and outfeed transport devices 111, 121 are operated to transport the first-received workpiece to the outfeed station 103, as illustrated in FIG. 4(c).

Where the first-received workpiece W is to be delivered in the inverted orient to the outfeed station 103, the drive assembly 137 is operated as follows.

Firstly, the first vacuum source 217 is operated, such as to apply a vacuum to the suction apertures 147a, b of the first workpiece support member 133. By the application of this vacuum, the first-received workpiece W is fixed to the first workpiece support member 133.

Then, as illustrated in FIG. 4(d), the outfeed transport device 121 is operated to move a workpiece W from the second workpiece support member 135, and in this embodiment the first drive unit 241 is operated to rotate the first drive member 161 and the first workpiece support member 133 which supports the workpiece W to be inverted.

As illustrated in FIG. 4(e), the first drive unit 241 continues to operate to rotate the first drive member 161 and the first workpiece support member 133, in this embodiment while the infeed transport device 111 is operated to transport a further workpiece W to the infeed station 101.

As illustrated in FIG. 4(f), the first drive unit 241 continues to operate to rotate the first drive member 161 and the first workpiece support member 133 and the second drive unit 243 is operated to rotate the second drive member 163 and the second workpiece support member 135, while the infeed transport device 111 continues to operate to transport the further workpiece W to the infeed station 101.

As illustrated in FIGS. 4(g) and (h), the first drive unit 241 continues to operate to rotate the first drive member 161 and the first workpiece support member 133, and the second drive unit 243 continues to operate to rotate the second drive member 163 and the second workpiece support member 135.

The first drive unit 241 continues to operate to rotate the first drive member 161 and the first workpiece support member 133 and the second drive unit 243 continues to operate to rotate the second drive member 163 and the second workpiece support member 135 until the first workpiece support member 133 reaches the workpiece-releasing configuration and the second workpiece support member 135 reaches the workpiece-receiving configuration.

Then, as illustrated in FIG. 4(i), the first vacuum source 217 is operated to release a vacuum from the suction apertures 147a, b of the first workpiece support member 133, in order to release the workpiece W from the first workpiece support member 133.

Subsequently, as illustrated in FIG. 4(j), the outfeed transport device 121 is operated to transport the released workpiece W from the outfeed station 103.

One of the straight-through or inverting modes as described hereinabove is then repeated using the second workpiece support member 135, which is at the workpiece-receiving configuration, depending upon whether the next received workpiece W is required to be inverted.

Finally, it will be understood that the present invention has been described in its preferred embodiments and can be modified in many different ways without departing from the scope of the invention as defined by the appended claims.

1. A workpiece handling apparatus for handling workpieces, comprising:
an infeed station at which workpieces are received;
an outfeed station from which workpieces are delivered; and
a workpiece inverting device which is operable to deliver a workpiece from the infeed station to the outfeed station in one of an orient as received at the infeed station or an inverted orient from the orient as received at the infeed station.

2. The apparatus of claim 1, wherein the infeed station comprises a workpiece transport device by which workpieces are transported to the infeed station, and by which workpieces can be transported from the infeed station to the outfeed station in the one orient and/or the outfeed station comprises a workpiece transport device by which workpieces are transported from the outfeed station, and by which workpieces can be transported from the infeed station to the outfeed station in the one orient.

3. (canceled)

4. The apparatus of claim 1, wherein the workpiece inverting device comprises first and second workpiece support members which are movably disposed relative to the infeed and outfeed stations, by which workpieces are delivered from the infeed station to the outfeed station in the inverted orient, and a drive assembly for moving the workpiece support members, optionally the workpiece support members are rotatable around a location which is between the infeed and outfeed stations.

5. (canceled)

6. The apparatus of claim 4, wherein the workpiece support members are each rotatable between a first, workpiece-receiving position in which the workpiece support member is adjacent a lower surface of a workpiece when located at the infeed station and disposed so as to allow a workpiece to pass thereover when being transported to the infeed station, and a second, workpiece-releasing position in which the workpiece support member is adjacent an upper surface of a workpiece when located at the outfeed station and being disposed so as to allow a workpiece to pass thereunder when being transported to or from the outfeed station, optionally the workpiece support members each comprise a support which supports a workpiece when being transferred from the infeed station to the outfeed station, and an arm by which the support is rotated between the infeed and outfeed stations, optionally the support has a planar support surface and includes at least one suction aperture, optionally a plurality of suction apertures, by which a reduced pressure or vacuum is applied to a workpiece in order to hold the same in a fixed position to the support.

7. (canceled)

8. (canceled)

9. The apparatus of claim 4, wherein the drive assembly comprises a first drive member to which the first workpiece support member is attached and a second drive member to which the second workpiece support member is attached, optionally the drive members are rotatable about an axis substantially perpendicular to a transport direction between the infeed and outfeed stations.

10. (canceled)

11. The apparatus of claim 9, wherein the drive members are independently rotatable relative to one another, allowing for the drive members to be rotated at different relative speeds, at least through part of a rotational phase.

12. The apparatus of claim 9, wherein the drive members extend laterally at a location between the infeed and outfeed stations.

13. The apparatus of claim 9, wherein the drive members are supported at ends thereof by first and second bearings, optionally the first drive member comprises an elongate, first drive element, one end of which is supported by the first bearing and the other end of which is supported by the second bearing, optionally the second drive member comprises an elongate, second drive element, one end of which is supported by the second bearing and the other end of which is supported by the first bearing, optionally the one end of the first drive element comprises a bore and the other end of the second drive element comprises a projection which is rotatably supported, optionally journalled, in the bore at the one end of the first drive element, and the one end of the second drive element comprises a bore and the other end of the first drive element comprises a projection which is rotatably supported, optionally journalled, in the bore at the one end of the second drive element.

14. (canceled)

15. (canceled)

16. (canceled)

17. The apparatus of claim 9, wherein the drive members are supported at one end thereof by respective ones of first and second bearings, optionally the first drive member comprises an elongate, first drive element, one end of which is supported by the first bearing, optionally the second drive member comprises an elongate, second drive element, one end of which is supported by the second bearing.

18. (canceled)

19. (canceled)

20. The apparatus of claim 9, wherein the first drive member is attached to the first workpiece support member, such that the first workpiece support member is rotated with rotation of the first drive member and/or the second drive member is attached to the second workpiece support member, such that the second workpiece support member is rotated with rotation of the second drive member.

21. (canceled)

22. The apparatus of claim 9, wherein the drive members are arranged in offset relation, such that, when the workpiece support members are in respective ones of the workpiece-receiving and workpiece-release positions, the workpiece support members provide a horizontally-extending aperture therebetween, which allows a workpiece to be transferred therebetween from the infeed to the outfeed stations in the same orient.

23. A workpiece inverting device for delivering workpieces selectively from an infeed station to an outfeed station in one of an orient as received at the infeed station or an inverted orient from the orient as received at the infeed station, wherein the workpiece inverting device comprises:
first and second workpiece support members which are movably disposed relative to the infeed and outfeed stations, by which workpieces are delivered from the infeed station to the outfeed station in the inverted orient; and
a drive assembly which comprises a first drive member to which the first workpiece support member is attached and a second drive member to which the second workpiece support member is attached;
wherein the drive members are arranged in offset relation such as to provide a horizontally-extending aperture therebetween, which allows a workpiece to be transferred therebetween from the infeed to the outfeed stations in the same orient.

24. A method of handling workpieces, comprising the steps of:
providing an infeed station at which workpieces are received;
providing an outfeed station from which workpieces are delivered;
providing a workpiece inverting device which is operable to deliver a workpiece from the infeed station to the outfeed station in one of an orient as received at the infeed station or an inverted orient from the orient as received at the infeed station; and
selectively operating the workpiece inverting device to deliver workpieces from the infeed station to the outfeed station in one of a pass-through mode, in which workpieces delivered to the outfeed station have an orient as received at the infeed station or an inverting mode, in which workpieces delivered to the outfeed station have an inverted orient from the orient of the workpieces as received at the infeed station.

25. The method of claim 24, wherein the infeed station comprises a workpiece transport device by which workpieces are transported to the infeed station, and by which workpieces can be transported from the infeed station to the outfeed station in the one orient and/or the outfeed station comprises a workpiece transport device by which workpieces are transported from the outfeed station, and by which workpieces can be transported from the infeed station to the outfeed station in the one orient.

26. (canceled)

27. The method of claim 24, wherein the workpiece inverting device comprises first and second workpiece support members which are movably disposed relative to the infeed and outfeed stations, by which workpieces are delivered from the infeed station to the outfeed station in the inverted orient, and a drive assembly for moving the workpiece support members, optionally the workpiece support members are rotatable around a location which is between the infeed and outfeed stations.

28. (canceled)

29. The method of claim 27, wherein the workpiece support members are each rotatable between a first, workpiece-receiving position in which the workpiece support member is adjacent a lower surface of a workpiece when located at the infeed station and disposed so as to allow a workpiece to pass thereover when being transported to the infeed station, and a second, workpiece-releasing position in which the workpiece support member is adjacent an upper surface of a workpiece when located at the outfeed station and being disposed so as to allow a workpiece to pass thereunder when being transported to or from the outfeed station.

30. The method of claim 27, wherein the workpiece support members each comprise a support which supports a workpiece when being transferred from the infeed station to the outfeed station, and an arm by which the support is rotated between the infeed and outfeed stations, optionally the support has a planar support surface and includes at least one suction aperture, optionally a plurality of suction apertures, by which a reduced pressure or vacuum is applied to a workpiece in order to hold the same in a fixed position to the support.

31. (canceled)

32. The method of claim 27, wherein the drive assembly comprises a first drive member to which the first workpiece support member is attached and a second drive member to which the second workpiece support member is attached, optionally the drive members are rotatable about an axis substantially perpendicular to a transport direction between the infeed and outfeed stations.

33. (canceled)

34. The method of claim 32, wherein the drive members are independently rotatable relative to one another, allowing for the drive members to be rotated at different relative speeds, at least through part of a rotational phase.

35. The method of claim 32, wherein the drive members extend laterally at a location between the infeed and outfeed stations.

36. The method of claim 32, wherein the drive members are supported at ends thereof by first and second bearings, optionally the first drive member comprises an elongate, first drive element, one end of which is supported by the first bearing and the other end of which is supported by the second bearing, optionally the second drive member comprises an elongate, second drive element, one end of which is supported by the second bearing and the other end of which is supported by the first bearing, optionally the one end of the first drive element comprises a bore and the other end of the second drive element comprises a projection which is rotatably supported, optionally journalled, in the bore at the one end of the first drive element, and the one end of the second drive element comprises a bore and the other end of the first drive element comprises a projection which is rotatably supported, optionally journalled, in the bore at the one end of the second drive element.

37. (canceled)

38. (canceled)

39. (canceled)

40. The method of claim 32, wherein the drive members are supported at one end thereof by respective ones of first and second bearings, optionally the first drive member comprises an elongate, first drive element, one end of which is supported by the first bearing, optionally the second drive member comprises an elongate, second drive element, one end of which is supported by the second bearing.

41. (canceled)

42. (canceled)

43. The method of claim 32, wherein the first drive member is attached to the first workpiece support member, such that the first workpiece support member is rotated with rotation of the first drive member and/or the second drive member is attached to the second workpiece support member, such that the second workpiece support member is rotated with rotation of the second drive member.

44. (canceled)

45. The method of claim 32, wherein the drive members are arranged in offset relation, such that, when the workpiece support members are in respective ones of the workpiece-receiving and workpiece-release positions, the workpiece support members provide a horizontally-extending aperture therebetween, which allows a workpiece to be transferred therebetween from the infeed to the outfeed stations in the same orient.

46. The method of claim 24, wherein, in the pass-through mode, the operating step comprises the steps of:
arranging workpiece support members in a configuration which allows a workpiece to be transported therebetween;
transporting a workpiece from the infeed station to the outfeed station in the one orient by operation of infeed and outfeed transport devices.

47. The method of claim 24, wherein, in an inverting mode, the operating step comprises the steps of:
engaging a workpiece to a first workpiece support member which is disposed therebeneath in a workpiece-receiving position at the infeed station, optionally by vacuum or reduced pressure;
rotating the first workpiece support member to a workpiece-releasing position at the outfeed station;
transporting a workpiece, if present, from the outfeed station during rotation of the first workpiece support member;
rotating a second workpiece support member from a workpiece releasing position at the outfeed station to a workpiece-receiving position at the infeed station;
transporting a workpiece to the infeed station during rotation of the second workpiece support member to the infeed station; and
disengaging the workpiece which is engaged to the first workpiece support member when disposed at the outfeed station.
